(19) United States
(12) Patent Application Publication
(10) Pub. No.: US 2015/0021176 A1
(43) Pub. Date: Jan. 22, 2015

(54) SPUTTERING DEVICE

(71) Applicant: NITTO DENKO CORPORATION, Osaka (JP)

(72) Inventors: Tomotake Nashiki, Osaka (JP); Akira Hamada, Osaka (JP)

(73) Assignee: NITTO DENKO CORPORATION, Osaka (JP)

(21) Appl. No.: 14/331,640

(22) Filed: Jul. 15, 2014

(30) Foreign Application Priority Data
Jul. 19, 2013 (JP) 2013-150074

(51) Int. Cl. H01J 37/32

(52) U.S. Cl. CPC H01J 37/32733
USPC 204/298.24

(57) ABSTRACT

In a sputtering device of the present invention, a long film is guided by a plurality of concave guide rolls. Pressure imposed on the long film from the plurality of concave guide rolls is strong as near as an end and is weak as near as the center. Accordingly, the long film is substantially supported in an end portion of each of the concave guide rolls. Since wrinkles generated on the long film are not subjected to strong pressure from the concave guide rolls when passing through the concave guide rolls, these wrinkles do not turn to folds and pass through as they are.

### BACKGROUND OF THE INVENTION

1. Field of the Invention

The present invention relates to a sputtering device configured to form a thin layer on a long film.

2. Description of Related Art

A sputtering method is widely used as a method for forming a thin layer in vacuum. In the sputtering method, plasma of sputtering gas is generated by applying a voltage between a base substrate and a target with the base substrate kept at an anodic potential and the target kept at a cathodic potential in a sputtering gas such as a low-pressure argon gas. Sputtering gas ions in the plasma strike the target, so that a constituent material of the target is driven out. The constituent material of the target, which is driven out, is deposited on the base substrate to form a thin layer.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is supplied in addition to a sputtering gas such as argon. In the reactive sputtering method, a constituent material of a target, which is driven out, reacts with a reactive gas, so that an oxide of the constituent material of the target is deposited on a base substrate.

In a sputtering device, a target and a cathode are usually mechanically and electrically integrated. The base substrate and the target face each other with a predetermined distance therebetween. The sputtering gas and the reactive gas are usually supplied between the base substrate and the target. The sputtering gas and the reactive gas may be supplied separately, or may be supplied in mixture.

In a sputtering device in which the base substrate is a silicon wafer or a glass plate, the base substrate is transferred using a robot arm, a roller conveyor, or the like. Rollers of a roller conveyor may be straight rollers each having a uniform diameter because the silicon wafer or the glass plate are neither stretched nor deformed.

However, when the base substrate is a long film, it is handled differently from the silicon wafer or the glass plate. A sputtering device and a sputtering method for a long film are described in, for example, JP 2001-073133 A.

In the case of a long film, it is impossible to form a sputtered layer over the whole of the long film at a time. Accordingly, the long film delivered from a supply roll is guided by a guide roll on a delivery side to a film depositing roll (also referred to as a can roll). The long film is wound around the film depositing roll by less than one round, and the film depositing roll is rotated at a constant speed to cause the long film to run at a constant speed. A film is deposited on a portion of the long film which faces the target. The long film after completion of film deposition is guided by a guide roll on a storage side and wound around a storage roll.

As the long film, single films or laminated films of polyethylene terephthalate, polybutylene terephthalate, polyamide, polyvinyl chloride, polycarbonate, polystyrene, polypropylene, polyethylene, and the like are generally used. In many cases, such polymer films are stretched in a width direction before being installed on a supply roll of a sputtering device.

The long film that has been stretched in a width direction tends to shrink the dimensions in the width direction when the temperature rises by contact with the film depositing roll. There is a possibility that wave-shaped wrinkles may be generated on the long film after film deposition because shrinkage of the dimensions in the width direction does not uniformly occur.

Wrinkles generated on the long film gradually disappear after allowing to stay the long film in a natural state. In the sputtering device, however, the long film after completion of depositing a film needs to be guided by a guide roll provided on a storage side. The wrinkles generated on the long film may turn to folds by pressure of the guide roll provided on the storage side. Since folds do not disappear, the folds become defective. It is necessary to prevent the wrinkles from turning to folds.

Depending on the material of the long film, the more the temperature increases by contact with the film depositing roll, the more the dimensions in a width direction of the long film becomes greater. In this case, there is also a possibility of generation of wrinkles on the long film after depositing a film. Such wrinkles turn to folds, which are defective.

When the temperature of the film depositing roll is high, there is a possibility that the temperature of the long film increases by radiant heat from the film depositing roll before the long film comes in contact with the film depositing roll, which may result in generation of wrinkles.

JP 2001-073133 A does not disclose that wrinkles are generated on a long film and these wrinkles turn to folds.

JP 2009-249047 A discloses a conveying device to correct meandering of a web and iron wrinkles of a long film. JP 2009-249047 A describes that “Since it has a property slid to the one where a conveying speed is quicker, the web under conveyance can expect the effect that will hold a web in the center and will inhibit meandering, if the crown roller is used. And if the crown roller is used, it can expect the effect that lengthens the wrinkles of a web because tension in a width direction may be imposed. And if the crown roller is used” However, JP 2009-249047 A does not disclose that wrinkles turn to folds and prevention of generation of folds.

### SUMMARY OF THE INVENTION

It is an object of the present invention to provide a sputtering device configured to prevent wrinkles generated on a long film from changing into folds.

The summary of the present invention is described as below.

A sputtering device of the present invention is configured to form a thin layer on a long film. In a first preferred aspect, a sputtering device according to the present invention comprises: a vacuum chamber; and a vacuum pump for evacuating the vacuum chamber. A film depositing roll, a target facing the film depositing roll, and a gas pipe are provided in the vacuum chamber. A gas pipe supplies a gas into the vacuum chamber. Further, a supply roll for supplying a long film and a storage roll for storing the long film, and a plurality of concave guide rolls for guiding conveyance of the long film are provided in the vacuum chamber. Each of the concave guide rolls has a great diameter in an end portion and has a small diameter in the center. Generally, the concave guide rolls each have a maximum diameter in the end portion and have a minimum diameter in the center.

In a second preferred aspect of the sputtering device according to the present invention, the plurality of concave guide rolls are guide rolls disposed on a downstream side of the travelling film depositing roll and arranged at least the nearest place to the film depositing roll.

In a third preferred aspect of the sputtering device according to the present invention, when the diameter of each of the concave guide rolls in the center is D1, the diameter of each of the concave guide rolls in the end portion is D2, a full length of each of the concave guide rolls is L, (D2−D1)/L is 0.00005 to 0.00125.

In a fourth preferred aspect of the sputtering device according to the present invention, the plurality of concave guide rolls to be used in the sputtering device are made from aluminum wherein a surface of each of the concave guide rolls is hard chrome-plated.

In the sputtering device of the present invention, a long film is guided by a plurality of concave guide rolls. Contact pressure between the long film and the plurality of concave guide rolls is strong as near as an end and is weak as near as the center. Accordingly, the long film is substantially supported in an end portion of each of the concave guide rolls. Since wrinkles generated on the long film are not subjected to strong pressure from the concave guide rolls when passing through the concave guide rolls, such wrinkles do not turn to folds and pass through as they are.

These wrinkles naturally disappear, resulting in no defect. In such a manner, the sputtering device of the present invention is capable of preventing generation of folds and defects.

For a full understanding of the present invention, reference should now be made to the following detailed description of the preferred embodiments of the invention as illustrated in the accompanying drawings.

### BRIEF DESCRIPTION OF THE DRAWINGS

FIG. 1 is an entire perspective view of a sputtering device of the present invention;

FIG. 2 (a) illustrates the time when a long film passes through a conventional straight guide roll;

FIG. 2 (b) illustrates the time when a long film passes through a concave guide roll to be used in the present invention;

FIG. 3 (a) is a perspective view of a first example of a concave guide roll to be used in the present invention;

FIG. 3 (b) is a perspective view of a second example of a concave guide roll to be used in the present invention;

FIG. 3 (c) is a perspective view of a third example of a concave guide roll to be used in the present invention; and

FIG. 3 (d) is a perspective view of a fourth example of a concave guide roll to be used in the present invention.

### DESCRIPTION OF THE PREFERRED EMBODIMENTS

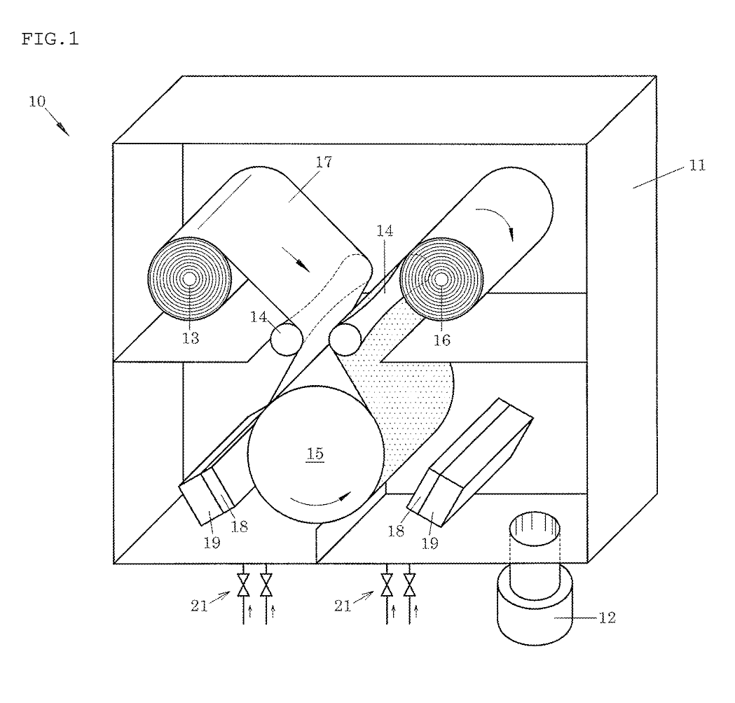

The preferred embodiments of the present invention will now be described with reference to FIGS. 1 to 3. Identical elements in the figure are designated with the same reference numerals.

FIG. 1 is an entire perspective view showing one example of a sputtering device 10 of the present invention. The sputtering device of the present invention comprises: a vacuum chamber 11; and a vacuum pump 12 for evacuating the vacuum chamber 11. A supply roll 13, a plurality of concave guide rolls 14, and a film depositing roll 15, and a storage roll 16 are provided in the vacuum chamber 11. A long film 17 is delivered from the supply roll 13 to be guided by the plurality of concave guide rolls 14. And the long film is wound around the film depositing roll 15 by less than one round to be guided by the concave guide rolls 14 again and is then stored in the storage roll 16.

A target 18 faces the film depositing roll 15 with a predetermined distance therebetween. The long film 17 continuously runs in synchronization with a rotation of the film depositing roll 15. A thin layer is adhered on the long film 17 so as to face the target 18. While FIG. 1 illustrates two targets 18, the number of targets 18 is not limited. To obtain an excellent film, the film depositing roll 15 is controlled to be at given temperatures within the scope of typically 20° C. to 250° C.

A sputtering gas (for instance, argon gas) and a reactive gas (for instance, oxygen gas) are supplied between respective targets 18 and the film depositing roll 15 from a gas pipe 21.

In the sputtering device 10 of the present invention, plasma of sputtering gas is generated by applying a voltage between the film depositing roll 15 and the target 18 with the film depositing roll 15 kept at an anodic potential and the target 18 kept at a cathodic potential in a sputtering gas such as a low-pressure argon gas. Sputtering gas ions in plasma strike the target 18, so that a constituent material of the target 18 is driven out. The constituent material of the target 18, which is driven out, is deposited on the long film 17 to form a thin layer.

As a transparent conductive layer, a thin layer of indium-tin-oxide (ITO) is widely used. When a thin layer of an oxide such as indium-tin-oxide (ITO) is formed, a reactive sputtering method is used. In the reactive sputtering method, a reactive gas such as oxygen is supplied in addition to a sputtering gas such as argon. In the reactive sputtering method, the constituent material of the target 18 (for example, indium atom, tin atom), which is driven out, reacts with a reactive gas, so that an oxide of the constituent material of the target 18 is deposited on the long film 17.

In the sputtering device 10 of the present invention, the target 18 and a cathode 19 are mechanically and electrically integrated. The long film 17 and the target 18 face each other with a predetermined distance therebetween. The sputtering gas and the reactive gas are supplied between the long film 17 and the target 18. The sputtering gas and the reactive gas may be supplied separately, or may be supplied in mixture.

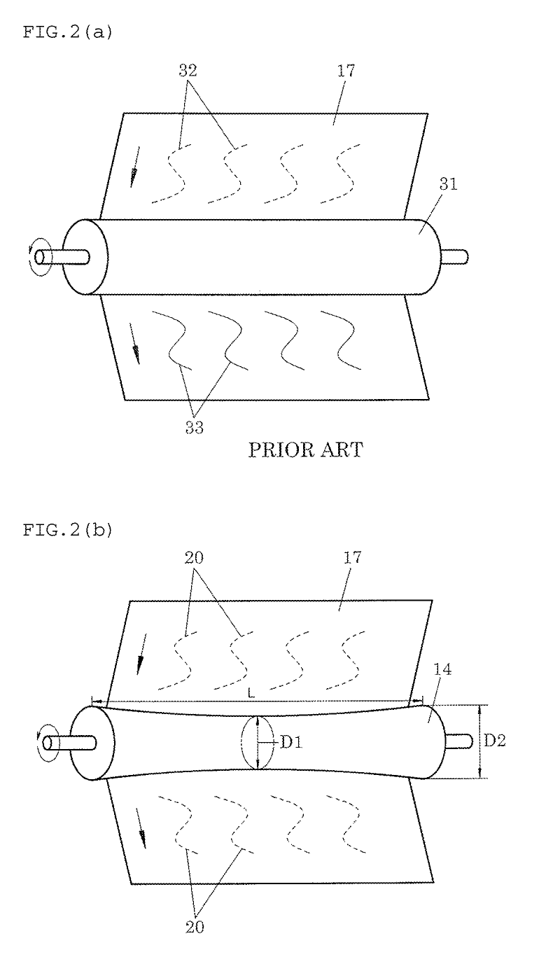

FIGS. 2 (a) and 2(b) illustrate effects of a concave guide roll 14 to be used for a sputtering device 10 of the present invention. FIG. 2 (a) illustrates the time when a long film 17 passes through a conventional guide roll 31 (a straight guide roll with a uniform diameter). FIG. 2 (b) illustrates the time when the long film 17 passes through the concave guide roll 14 to be used in the present invention.

There is a possibility that the long film 17 may irregularly shrink by being heated by the film depositing roll 15, which results in generation of wrinkles 32, 20. Since the conventional guide roll 31 shown in FIG. 2 (a) has a uniform diameter, strong pressure is imposed on a portion of the wrinkles 32. Accordingly, as shown in FIG. 2 (a), when portions of the wrinkles 32 pass through the guide roll 31, the wrinkles may turn to folds 33 by the application of strong pressure. The folds 33 do not disappear and become defective.

In the concave guide roll 14 in FIG. 2 (b), a line to connect an end portion to a central portion is an arc and the diameter of the concave guide roll 14 continuously decreases from the end portion to the central portion. In the concave guide roll 14 to be used in the present invention, a diameter D2 in an end portion is the maximum and a diameter D1 in the central portion is the minimum. Little pressure is imposed on the portions of the wrinkles 20 because the long film 17 is substantially supported by an end portion of the concave guide roll 14. As a result, even after the wrinkles 20 pass through the concave guide roll 14, the wrinkles 20 remain as they are and do not turn to folds. The wrinkles 20 naturally disappear while the long film 17 runs and do not become defective.

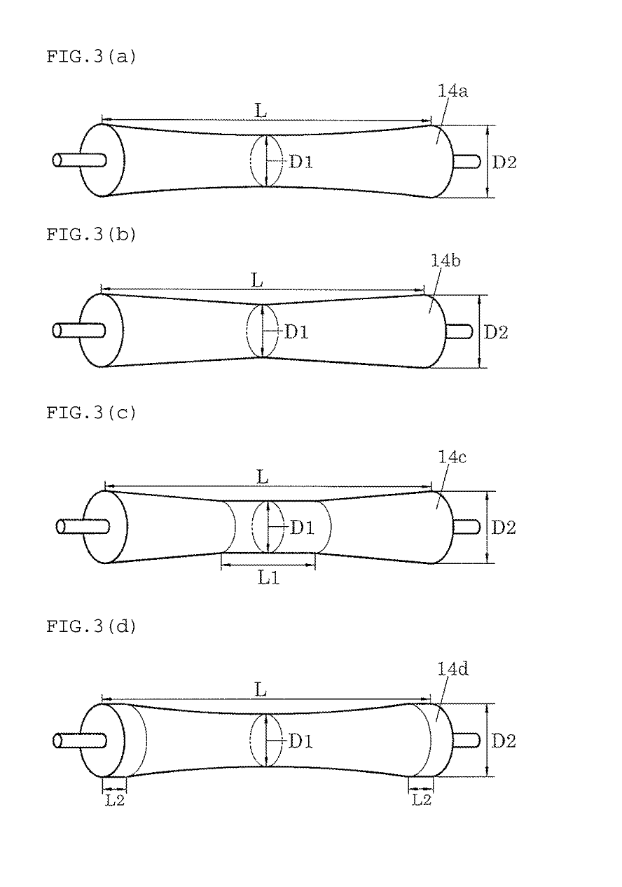

FIG. 3 (a) is a perspective view of a first example of a concave guide roll 14a to be used in the present invention. The concave guide roll 14a shown in FIG. 3 (a) is identical to the concave guide roll 14 shown in FIG. 2 (b).

FIG. 3 (b) is a perspective view of a second example of a concave guide roll 14b to be used in the present invention. In the concave guide roll 14b shown in FIG. 3 (b), a line to connect an end portion to a central portion is a straight line. That is, the concave guide roll 14b is in a shape in which two rolls with taper are butted with a smaller diameter in the center. In the concave guide roll 14b, the diameter in the central portion is D1 and the diameter in an end portion is D2.

FIG. 3 (c) is a perspective view of a third example of a concave guide roll 14c to be used in the present invention. The concave guide roll 14c is straight-typed where a portion of a length L1 in a width direction of a central portion is the diameter D1 and the outside thereof is a roll with taper. That is, the concave guide roll 14c is in a shape in which a side of a smaller diameter of two rolls with a partial taper is butt with the center. An end portion of the diameter of the concave guide roll 14c is D2.

FIG. 3 (d) is a perspective view of a fourth example of a concave guide roll 14d to be used in the present invention. In the concave guide roll 14d, a portion of a length L2 in a width direction in both end portions is a straight type, and an inside side thereof is connected by an arc so that the central part may be the minimum diameter D1. The diameter of a portion of the length L2 in a width direction in both end portions of the concave guide roll 14c is D2.

In the sputtering device 10 of the present invention, an object of using a plurality of concave guide rolls 14 is not to impose tension on the long film 17 in a width direction. It is an object of using a plurality of concave guide rolls 14 to support end portions of the long film 17 by end portions of the concave guide rolls 14 not to apply pressure on portions other than the end portions of the long film 17.

In the sputtering device 10 of the present invention, the concave guide rolls 14 are used as guide rolls that are disposed on a downstream side of the conveying long film 17 and are at least the closest to the film depositing roll 15. The long film 17 is heated by the film depositing roll 15. As a result, in many cases, wrinkles 20 are generated. There is a case where wrinkles 20 are also generated on an upstream side of the film depositing roll 15 in the long film 17 by radiation heat. Accordingly, the concave guide rolls 14 are preferably used also as guide rolls disposed on an upstream side of a film depositing roll.

While FIG. 1 shows two concave guide rolls 14 for the purpose of explanation, a greater number of guide rolls (in the case of a large-size sputtering device, 100 or greater guide rolls) are actually used. In any guide roll, strong pressure is not preferably imposed on the long film 17 except for both end portions of the long film 17. As a result, all guide rolls are preferably concave guide rolls 14.

According to an experiment of inventors of the present Invention, an appropriate quantity of dent for each of the concave guide rolls 14 depends on a full length of each of the concave guide rolls 14. When the diameter in the central portion of each of the concave guide rolls 14 is D1, the diameter of the end portion is D2, and the full length is L, a quantity of dent (D2−D1) is preferably within a scope where (D2−D1)/L is 0.00005 to 0.00125.

Examples where preferable results were obtained in an experiment include the results that when the concave guide rolls 14 each have a full length L of 1700 mm, the difference between the diameter D2 in the end portion and the diameter D1 in the central portion that was within a scope of 0.085 mm to 2.125 mm (D2>D1).

When (D2−D1)/L is not greater than 0.00005, the quantity of dent in the central portion becomes too small and the shape is closer to a straight guide roll 31. Accordingly, strong pressure is imposed on the portions of the wrinkles 20, which may turn to folds 33.

On the contrary, when (D2−D1)/L is over 0.00125, the quantity of dent in the central portion becomes too great and a gap between each of the concave guide rolls 14 and the long film 17 is too great, resulting in unstable guide.

The concave guide rolls 14 to be used in the present invention are preferably hard chrome-plated on a surface of the body made of aluminum and a surface of hard chrome plating is preferably mirror finished. Since the aluminum body of each of the concave guide rolls 14 is light-weighed and has a small moment of inertia, each of the concave guide rolls 14 easily rotates in accordance with the conveying rate of the long film 17. There are no fears that the mirror finished surface may easily get scratches and dirty, results in no possibility of the long film 17 being damaged because hard chrome plating is hard and is corrosion-inhibiting.

When the long film 17 is charged, insulating concave guide rolls whose contact surfaces with the long film 17 are kept at a floating potential may be used so that static electricity may not be discharged from the long film 17 to the concave guide rolls 14. The insulating concave guide rolls in which contact surfaces of the concave guide rolls with the long film 17 are coated with an insulator, such as aluminum oxide, silicon nitride or the like. Alternatively, a contact surface of the long film 17 is a metal surface which is hard chrome-plated, however, an insulating bush is engaged with a bearing portion to insulate a bearing and a shaft of each concave guide roll.

### INDUSTRIAL APPLICABILITY

The sputtering device of the present invention is useful for forming a thin layer, particularly, a transparent conductive layer of indium-tin-oxide (ITO) or the like, on a long film.

This application claims priority from Japanese Patent Application No. 2013-150074, which is incorporated herein by reference.

There has thus been shown and described a novel sputtering device which fulfills all the objects and advantages sought therefore. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

What is claimed is:

1. A sputtering device configured to form a thin layer on a long film, the sputtering device comprising:
a vacuum chamber;
a vacuum pump for evacuating the vacuum chamber;
a film depositing roll provided in the vacuum chamber;
a target facing the film depositing roll;
a gas pipe for supplying a gas into the vacuum chamber;
a supply roll for supplying the long film;
a storage roll for storing the long film; and
a plurality of concave guide rolls for guiding conveyance of the long film, the plurality of concave guide rolls each having a great diameter in an end portion and a small diameter in the center.

2. The sputtering device according to claim 1, wherein the plurality of concave guide rolls are guide rolls disposed on a downstream side of the travelling film depositing roll and arranged at least the nearest place to the film depositing roll.

3. The sputtering device according to claim 1, when the diameter of each of the concave guide rolls in the center is D1 and the diameter of each of the concave guide rolls in the end portion is D2, and a full length of each of the concave guide rolls is L, (D2−D1)/L is 0.00005 to 0.00125.

4. The sputtering device according to claim 1, wherein the plurality of concave guide rolls are made from aluminum in which a surface of each of the concave guide rolls is hard chrome-plated.
